(19) United States
(12) Patent Application Publication
(10) Pub. No.: US 2007/0235809 A1
(43) Pub. Date: Oct. 11, 2007

(54) Semiconductor device

(75) Inventor: Kiminori Hayano, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/783,095

(22) Filed: Apr. 5, 2007

(30) Foreign Application Priority Data
Apr. 6, 2006 (JP) 2006-105355

(51) Int. Cl. H01L 23/62

(52) U.S. Cl. 257/355

(57) ABSTRACT

A semiconductor device includes electrostatic protection circuit Q formed by connecting first NMOS transistor Q1 having first threshold voltage and second NMOS transistor Q2 having second threshold voltage lower than the first threshold voltage in parallel between power supply terminal N1 and ground terminal N2. Film thickness of gate insulating film 4 of the second NMOS transistor Q2 is formed to be thinner than that of gate insulating film 5 of the first NMOS transistor Q1. A source/drain region 7b of the transistor Q1 and a source/drain region 7d of the transistor Q2 are connected to power supply terminal N1. Source/drain region 7a of transistor Q1, gate electrode 5a of transistor Q1, source/drain region 7c of transistor Q2, gate electrode 5b of transistor Q2, and substrate 1 are connected to ground terminal N2. Leak current and operation start voltage are reduced.

### FIELD OF THE INVENTION

The present invention relates to a semiconductor device. More specifically, the invention relates to a semiconductor device including an electrostatic protection circuit.

### BACKGROUND OF THE INVENTION

In semiconductor devices, in order to protect an internal circuit formed of transistors or the like from electrostatic application from outside, an electrostatic protection circuit is connected to an external terminal. Then, this electrostatic protection circuit is connected to a power supply terminal as well as an input signal terminal and a data output terminal. As a typical electrostatic protection circuit, there is provided the electrostatic protection circuit in which an NMOS transistor is connected between the power supply terminal and a ground terminal (refer to Patent Documents 1 to 4, for example).

### SUMMARY OF THE DISCLOSURE

The following considerations are given on the related art by the present invention.

FIG. 9 is an equivalent circuit diagram of the electrostatic protection circuit as described above. Reference numeral N1 denotes the power supply terminal, reference numeral N2 denotes the ground terminal. Reference numeral Q51 denotes the electrostatic protection circuit, and reference numeral Q4 denotes the internal circuit. The electrostatic protection circuit Q51 is formed of the NMOS transistor. A characteristic required for the electrostatic protection circuit is that the circuit quickly responses to the electrostatic application, and reduces a voltage to be applied to the internal circuit with sufficient discharging capability.

(A) of FIG. 10 shows a current-voltage characteristic showing an operating state of the electrostatic protection circuit. Referring to (A) of FIG. 10, reference numeral V₁ denotes an operation stating voltage, while reference numeral Iₜ₂ denotes a current at a time of a breakdown. Referring to (A) of FIG. 10, when an electrostatic stress is applied from outside, an intensity of an electric field applied between a drain and a gate increases. A gate-side depletion layer of the drain is therefore bent, so that the electric field becomes strong. A breakdown of the gate-side depletion layer occurs on a P-type substrate, so that a current flows to a semiconductor substrate. Then, a substrate potential rises. A lateral bipolar constituted from a collector formed of an N-type impurity region of the drain of the NMOS transistor, a base formed of the P-type substrate, and an emitter formed of an N-type impurity region of a source of the NMOS transistor is turned on and then enters into a snapback. Then, the electrostatic protection device operates (refer to the voltage V₁ in (A) of FIG. 10. When the circuit has once entered into a snapback state and operates, a large current can be flown. The applied electrostatic stress can be thereby discharged to a ground side (GND side). Then, when the applied electrostatic stress increases, the current that flows through the electrostatic protection circuit also increases. At last, the electrostatic protection circuit itself breaks down (refer to the current Iₜ₂).

The operation start voltage or a snapback start voltage of the electrostatic protection circuit showing the characteristic as described above is first set to be low. Ideally, the operation start voltage or the snapback start voltage is set to be lower than a gate insulating film breakdown voltage (refer to a voltage “VOX” in (A) of FIG. 10) of a transistor of the internal circuit. Further, the electrostatic protection circuit is set to have sufficient discharging capability so that a voltage generated inside after the snapback becomes lower than the gate insulating film breakdown voltage of the transistor in the internal circuit.

In order to increase the discharging capability of the electrostatic protection circuit, it is effective to increase the size of the protection circuit itself or reduce a wiring resistance of a ground terminal, which is a discharging destination. On the other hand, in order to reduce the operation start voltage, reduction of a thickness of a gate insulating film of the NMOS transistor of the electrostatic protection circuit may be considered. It is because, when the thickness of the gate insulating film is reduced, the intensity of the electric field applied between the drain and the gate at the time of the electrostatic stress application will increase, so that the NMOS transistor will break down with a low applied voltage.

(B) of FIG. 10 is a graph showing a relationship between a breakdown voltage Vbd of the NMOS transistor and a thickness Tₒₓ of the gate insulating film. (B) of FIG. 10 shows that as the thickness of the gate insulating film is reduced, the breakdown voltage decreases. Special setting of the gate insulating film for the electrostatic protection circuit complicates a manufacturing step. Accordingly, it has become common practice to select an optimum transistor from among some NMOS transistors used inside the semiconductor device, and then to employ the optimum transistor for the electrostatic protection circuit.

In order to suppress variations in a supply potential and a ground potential during a circuit operation, a plurality of power supply terminals and ground terminals are arranged on a semiconductor substrate. Further, in order to prevent noise induced when a certain circuit operates from affecting an operation of another circuit, a power supply terminal and a ground terminal dedicated to a specific circuit are sometimes provided. Further, with an increase in an integration degree of the semiconductor device, the number of power supply terminals and the number of ground terminals on the semiconductor substrate tend to increase.

As a measure against electrostatic application from outside, the electrostatic protection circuit is connected to each power supply terminal, as in other signal and data input/output terminals. Then, since the number of the power supply terminals is increased, the electrostatic protection circuits of an extremely large size in view of the semiconductor device as a whole are connected. The size of each electrostatic protection circuit is designed to be such a size that, when an electrostatic stress is applied to an external terminal to which the electrostatic protection circuit is connected, the electrostatic protection circuit has discharging capability that is enough to protect a circuit connected inside the semiconductor device and the electrostatic protection circuit itself does not break down. The electrostatic stress is applied from outside of the semiconductor device. Accordingly, when a plurality of power supply terminals on the semiconductor substrate are connected to one terminal arranged outside a package, considering that the applied electrostatic stress is distributed across the semiconductor device, reduction of the size of the electrostatic protection circuit connected to one of the power supply terminals on the semiconductor substrate can also be performed.
[Patent Document 1] JP Patent Kokai Publication No. JP-A-8-204176
[Patent Document 2] JP Patent Kokai Publication No. JP-A-8-288404
[Patent Document 3] JP Patent Kokai Publication No. JP-A-11-87727
[Patent Document 4] JP Patent Kokai Publication No. JP-A-9-36242

The entire disclosures of the above mentioned Patent Documents are incorporated herein by reference thereto. In the course of research toward the present invention, the following analyses have been made.

However, in recent years, assembly of different semiconductor devices into a same package has been performed. In such a case, a semiconductor device in a wafer state is shipped to a client. Then, the client combines the semiconductor device with other semiconductor device, for assembly. Hence, it is not known how a power supply terminal on a semiconductor substrate is connected to a terminal of the package. For this reason, in such a case, it is necessary to connect an electrostatic protection circuit having a sufficient size to each power supply terminal on the semiconductor substrate. To take a dynamic random access memory (hereinafter referred to as a DRAM) as an example, a feature size of the DRAM may reach as long as 5000 to 10000 micrometers. When the electrostatic protection circuit having the large size as described above is connected, a proportion of a standby current that will be flown through the electrostatic protection circuit to standby currents of the semiconductor device may increase to be considerably large.

As a most common electrostatic protection circuit, assume an electrostatic protection circuit formed of an NMOS transistor. Then, this standby current becomes a sum of leak currents when the NMOS transistor is in an off state. This leak current is related to a threshold voltage of the NMOS transistor. (C) of FIG. 10 is a graph showing a relationship between a leak current Iₗₑₐₖ and a threshold voltage Vₜₕ when the NMOS transistor is in the off state. It can be seen that as the threshold voltage is lowered, the leak current greatly increases.

In recent years, a supply voltage is increasingly lowered so as to reduce current consumption of the semiconductor device. Then, both the gate insulating film thickness and the threshold voltage of the NMOS transistor are increasingly reduced so that the NMOS transistor has sufficient current capacity even if the supply voltage is lowered. (D) of FIG. 10 is a graph showing a relationship between the gate insulating film thickness Tₒₓ and the threshold voltage Vₜₕ of the NMOS transistor. This tendency brings about an increase in the leak current of the NMOS transistor. Hence, in the semiconductor device for which a small standby current is demanded, reduction of the leak current when the NMOS transistor is in the off state as much as possible has become a requirement in the transistor development.

Since the size of a protection device connected to the power supply terminal as described above is very large, the leak current in the semiconductor device as a whole may become considerably large even if the leak current of the NMOS transistor as a discrete device is reduced. As a measure against this problem, use of a transistor having a thick gate insulating film and a large threshold voltage as the protection device may be considered. In the case of the DRAM, a signal that drives a word line of a memory cell is boosted to a high voltage equal to or larger than an ordinary supply voltage. Thus, an NMOS transistor having a thick gate insulating film is used in these circuits for performing voltage boosting and driving the word line, thereby preventing breakdown even at a high voltage. As described above, the threshold voltage of the NMOS transistor having the thick gate insulating film is also high. As a result, the leak current in the off state is also reduced. When attention is focused on the leak current alone, use of the NMOS transistor having the thick gate insulating film as the electrostatic protection circuit for the power supply terminal is effective for reducing the standby current. However, the thickness of the gate insulating film is originally increased so as to increase the breakdown voltage. Accordingly, the operation start voltage of the electrostatic protection circuit may also be thereby increased. Then, the electrostatic protection circuit may not be able to sufficiently protect the internal circuit.

In the case of the input signal terminal, as a measure against an increase in the operation start voltage of the electrostatic protection circuit, a resistance element can be connected between the input signal terminal and the internal circuit so as to delay propagation of the electrostatic stress to the internal circuit. In the case of the power supply terminal, however, the connection as described above greatly affects the operating speed of the internal circuit. Accordingly, the measure as described above cannot be adopted.

As another measure for reducing the leak current, series-connection of a plurality of NMOS transistors can be conceived. In FIG. 11, two NMOS transistors Q51 and Q52 are connected in series. As the two NMOS transistors, the same transistors or a combination of an NMOS transistor with a thick gate insulating film and an NMOS transistor with a thin gate insulating film may be employed.

However, when the electrostatic protection circuit is formed of the two NMOS transistors connected in series as described above, the two NMOS transistors must operate so as to operate as the electrostatic protection circuit. Thus, a problem arises that an increase in the operation start voltage or reduction of the discharging capability may be brought about, and the electrostatic protection circuit therefore may not be able to protect the internal circuit.

It is an object of the present invention to reduce a leak current and also reduce an operation start voltage of a protection device, thereby causing an electrostatic circuit to exhibit sufficient capability as an electrostatic protection circuit.

According to a first aspect of the present invention, a semiconductor device comprises: an electrostatic protection circuit formed by connecting a first MOS transistor having a first threshold voltage and a second MOS transistor having a second threshold voltage lower than the first threshold voltage in parallel between two external terminals.

In the semiconductor device of the present invention, the following modes may be carried out with advantage: It is preferable that a film thickness of a gate insulating film of the second MOS transistor is formed to be thinner than a film thickness of a gate insulating film of the first MOS transistor.

In the semiconductor device of the present invention, it is preferable that the first MOS transistor and the second MOS transistor are formed on a same substrate.

Preferably, in the semiconductor device of the present invention, a first external terminal of the two external terminals is one of a power supply terminal, an input signal terminal, and a data output terminal; and a second external terminal of the two external terminals is a ground terminal.

Preferably, the semiconductor device of the present invention further includes: a third external terminal other than the two external terminals; and a further (other) electrostatic protection circuit connected between the first external terminal and the third external terminal.

Preferably, in the semiconductor device of the present invention, the first MOS transistor and the second MOS transistor are NMOS transistors; and the further (other) electrostatic protection circuit is formed of a PMOS transistor.

Preferably, in the semiconductor device of the present invention, one of a source and a drain of the first MOS transistor is connected to the first external terminal; one of a source and a drain of the second MOS transistor is connected to the first external terminal; the other of the source and the drain of the first MOS transistor and a gate electrode of the first MOS transistor are connected to the second external terminal; the other of the source and the drain of the second MOS transistor and a gate electrode of the second MOS transistor are connected to the second external terminal; and a substrate or a well forming a channel of the first MOS transistor and a channel of the second MOS transistor is connected to the second external terminal.

Preferably, in the semiconductor device of the present invention, the channel of the first MOS transistor and the channel of the second MOS transistor are formed in a first well; a second well of a conductivity type opposite to a conductivity type of the first well and the substrate is disposed between the first well and the substrate; and the second well is connected to the first external terminal.

Preferably, in the semiconductor device of the present invention, the first MOS transistor and the second MOS transistor are adjacent to each other; and one of the source and the drain of the first MOS transistor and one of the source and the drain of the second MOS transistor are common.

Preferably, in the semiconductor device of the present invention, the first MOS transistor and the second MOS transistor are adjacent to each other; and the semiconductor device includes a device separation region that separates one of the source and the drain of the first MOS transistor from one of the source and the drain of the second MOS transistor.

According to a second aspect, there is provided a semiconductor device comprising: a first electrostatic protection circuit connected across a signal line terminal and a ground terminal; a second electrostatic protection circuit connected across the signal line terminal and the ground terminal; and an internal circuit connected across the power supply terminal and the ground terminal; the first electrostatic protection circuit being formed of a parallel connection of a first MOS transistor having a first threshold voltage and a second MOS transistor having a second threshold voltage lower than the first threshold voltage; the signal line terminal being connected to a gate of the internal circuit via a resistance; wherein the second electrostatic protection circuit is formed of a MOS transistor having a different conductive type from the first and second MOS transistors of the first electrostatic protection circuit.

Preferably, the second MOS transistor has a gate insulating film thinner than the first MOS transistor.

Preferably, the second electrostatic protection circuit is formed of a MOS transistor having a different conductive type from the MOS transistors of the first electrostatic protection circuit.

According to a third aspect, there is provided a semiconductor device comprising: an electrostatic protection circuit connected across a power supply terminal and a ground terminal; and an internal circuit connected across the power supply terminal and the ground terminal in parallel with the electrostatic protection circuit; wherein the electrostatic protection circuit is formed of a parallel connection of a first MOS transistor having a first threshold voltage and a second MOS transistor having a second threshold voltage lower than the first threshold voltage.

Preferably, the second MOS transistor has a gate insulating film thinner than the first MOS transistor.

The meritorious effects of the present invention are summarized as follows.

According to the present invention (in the first aspect and the modes), an electrostatic protection circuit for a power supply terminal is formed of an MOS transistor having a high threshold voltage, thereby allowing provision of a semiconductor device having a small standby current. Further, by connecting an MOS transistor having a low threshold voltage in parallel in the electrostatic protection circuit for the power supply terminal, the semiconductor device can be provided in which the electrostatic protection circuit can be operated at a low voltage, and a function as the electrostatic protection circuit will not be impaired when an electrostatic stress is applied.

### BRIEF DESCRIPTION OF THE DRAWINGS

FIG. 1 includes drawings schematically showing a configuration of a semiconductor device according to a first example of the present invention, (A) of FIG. 1 is a circuit diagram, and (B) of FIG. 1 is a partial sectional view of an electrostatic protection circuit;

FIG. 2 is a graph schematically showing a current-voltage characteristic of the electrostatic protection circuit of the semiconductor device according to the first example of the present invention;

FIG. 3 includes drawings schematically showing a configuration of a semiconductor device according to a second example of the present invention, (A) of FIG. 3 is a circuit diagram, (B) of FIG. 3 is a partial plan view of an electrostatic protection circuit, and (C) of FIG. 3 is a partial sectional view of the electrostatic protection circuit taken along a line X-X′;

FIG. 4 includes step sectional views schematically showing a manufacturing method of the electrostatic protection circuit of the semiconductor device according to the second example of the present invention;

FIG. 5 is a partial sectional view schematically showing a configuration of a semiconductor device according to a third example of the present invention;

FIG. 6 includes drawings schematically showing a configuration of a semiconductor device according to a fourth example of the present invention, (A) of FIG. 6 shows a partial plan view of an electrostatic protection circuit, and (B) of FIG. 6 is a partial sectional view of the electrostatic protection circuit taken along a line Y-Y′;

FIG. 7 is a circuit diagram schematically showing a configuration of a semiconductor device according to a fifth example of the present invention;

FIG. 8 is a circuit diagram schematically showing a configuration of a semiconductor device according to a sixth example of the present invention;

FIG. 9 is a circuit diagram schematically showing a configuration of a semiconductor device including one electrostatic protection circuit;

FIG. 10 includes drawings schematically showing an electric characteristic of the electrostatic protection circuit, (A) of FIG. 10 is a current-voltage characteristic diagram showing an operating state of the electrostatic protection circuit, (B) of FIG. 10 is a graph showing a relationship between a breakdown voltage of an NMOS transistor and a gate insulating film thickness of the NMOS transistor, (C) of FIG. 10 is a graph showing a relationship between a leak current and a threshold voltage of the NMOS transistor when the NMOS transistor is in an off state, and (D) of FIG. 10 is a graph showing a relationship between the gate insulating film thickness of the NMOS transistor and the threshold voltage of the NMOS transistor; and

FIG. 11 is a circuit diagram schematically showing a configuration of a semiconductor device that includes an electrostatic protection circuit in which two NMOS transistors are connected in series.

### PREFERRED MODES OF THE DISCLOSURE

### FIRST EXAMPLE

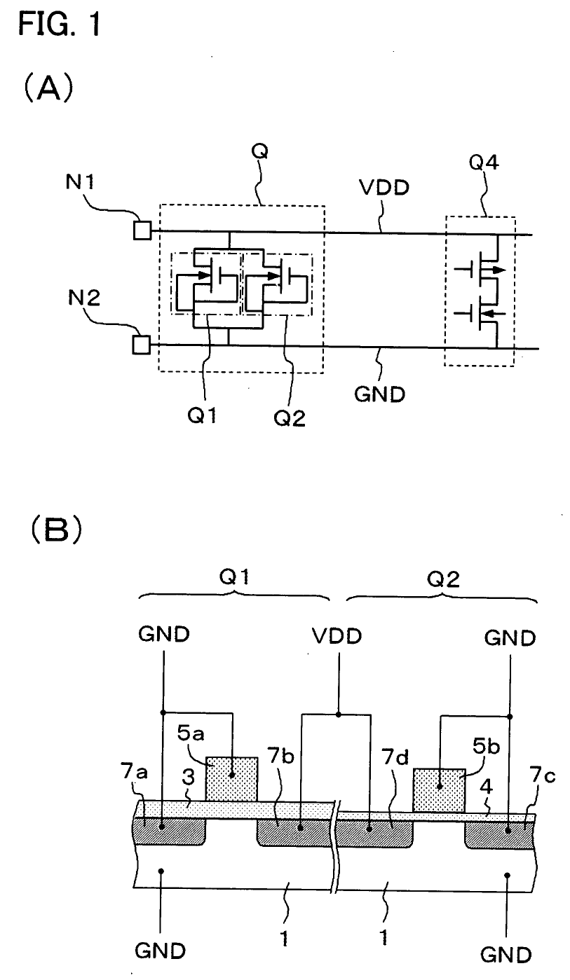

A semiconductor device according to a first example of the present invention will be described, using drawings. FIG. 1 includes drawings schematically showing a configuration of the semiconductor device according to the first example of the present invention. FIG. 1(A) is a circuit diagram, and (B) of FIG. 1 is a partial sectional view of an electrostatic protection circuit.

Referring to (A) of FIG. 1, this semiconductor device is a semiconductor device used in a cellular phone or a portable terminal for which an extremely small standby current is required, for example. The semiconductor device includes an internal circuit Q4 with MOS transistors connected in series between a power supply (power supply line VDD) and a ground (ground line GND), and an electrostatic protection circuit Q including an NMOS transistor Q1 having a thick gate insulating film and an NMOS transistor Q2 having a thin gate insulating film connected in parallel between the power supply and the ground. The electrostatic protection circuit Q is connected in parallel with the internal circuit Q4 between the power supply and the ground. A power supply terminal N1, which is intended to be an external terminal, is provided at one end of the power supply line VDD. A ground terminal N2, which is intended to be an external terminal, is provided at one end of the ground line GND.

A sum of sizes of two types of the NMOS transistors Q1 and Q2 is determined so that the electrostatic protection circuit Q has sufficient discharging capability, and a ratio between the sizes of the respective NMOS transistors Q1 and Q2 is determined in view of all leak currents of the electrostatic protection circuit connected to the power supply terminal N1. More specifically, when the size ratio of the NMOS transistor Q1 having the thick gate insulating film is set to be large, the leak currents of the electrostatic protection circuit Q decrease.

Referring to (B) of FIG. 1, the electrostatic protection circuit Q of the semiconductor device is mainly formed of a P-type semiconductor substrate 1, a first gate insulating film 3, a second gate insulating film 4, a first gate electrode 5a, a second gate electrode 5b, and N-type impurity regions 7a, 7b, 7c, and 7d. In order to facilitate understanding of a wiring configuration in (B) of FIG. 1, an interlayer insulating film, wiring, and via holes are omitted.

The P-type semiconductor substrate 1 is the P-type semiconductor substrate (a silicon substrate), and is electrically connected to the ground (GND). A P-type well may be used in place of the P-type semiconductor substrate 1. The first gate insulating film 3 is an insulating film (such as a silicon oxide film, a silicon oxo-nitride film, or the like) disposed at least between the first gate electrode 5a of the NMOS transistor Q1 and a channel of the NMOS transistor Q1, and is formed to be thicker than a film thickness of the second gate insulating film 4. The second gate insulating film 4 is an insulating film (such as the silicon oxide film, silicon oxo-nitride film, or the like) disposed at least between the second gate electrode 5b of the NMOS transistor Q2 and a channel of the NMOS transistor Q2, and is formed to be thinner than a film thickness of the first gate insulating film 3.

The first gate electrode 5a is a gate electrode made of a conductor (such as polysilicon, a metal, or the like, for example) disposed on the first gate insulating film 3 of the NMOS transistor Q1, and is electrically connected to the ground (GND). The second gate electrode 5b is a gate electrode made of the conductor (such as the polysilicon, metal, or the like) disposed on the second gate insulating film 4 of the NMOS transistor Q2, and is electrically connected to the ground (GND).

The N-type impurity regions 7a, 7b, 7c, and 7d are impurity diffusion regions in which impurities of an N type, which is a conductivity type opposite to that of the P-type semiconductor substrate 1, are diffused. The N-type impurity regions 7a and 7b are disposed on both sides of the channel of the NMOS transistor Q1 and become source/drain regions of the NMOS transistor Q1. The N-type impurity region 7a is electrically connected to the ground (GND), while the N-type impurity region 7b is electrically connected to the power supply (VDD). The N-type impurity regions 7c and 7d are disposed on both sides of the channel of the NMOS transistor Q2 and become source/drain regions of the NMOS transistor Q2. The N-type impurity region 7c is electrically connected to the ground (GND), while the N-type impurity region 7d is electrically connected to the power supply (VDD).

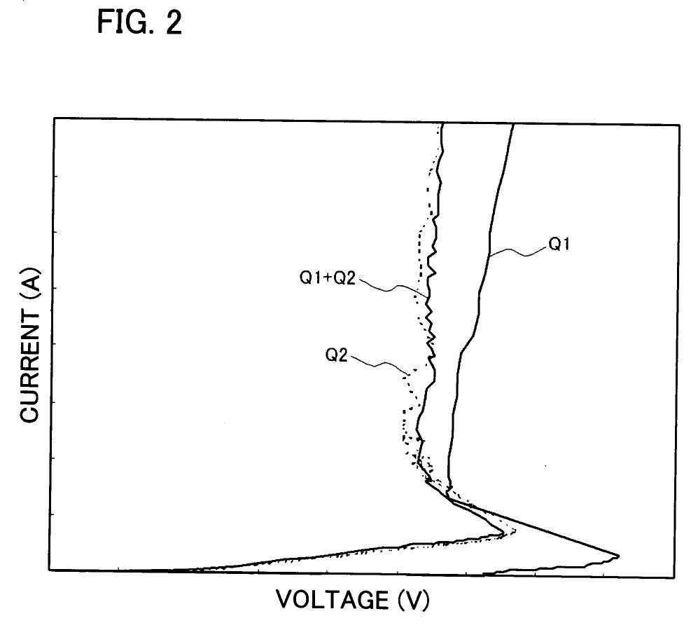

Next, a current-voltage characteristic of the electrostatic protection circuit of the semiconductor device according to the first example of the present invention will be described. FIG. 2 is a graph schematically showing the current-voltage characteristic of the electrostatic protection circuit of the semiconductor device according to the first example of the present invention.

When the current-voltage characteristic of the electrostatic protection circuit of the semiconductor device is measured, a device for performing evaluation referred to as TLP (Transmission Line Pulsing) measures the current-voltage characteristic when an electric current pulse of a fixed time width is applied to the electrostatic protection circuit.

Referring to FIG. 2, a solid line Q1 on the right (of a comparative example 1) shows a characteristic of the electrostatic protection circuit formed only of the NMOS transistor Q1 having the thick gate insulating film. A broken line Q2 (of a comparative example 2) shows a characteristic of the electrostatic protection circuit formed only of the NMOS transistor Q2 having the thin gate insulating film. As seen from FIG. 2, it can be understood that the electrostatic protection circuit formed of the NMOS transistor Q2 having the thin gate insulating film starts operation at a lower voltage. In other words, when the NMOS transistor Q1 having the thick gate insulating film is employed in order to reduce a leak current of the NMOS transistor used as the electrostatic protection circuit, an operation start voltage of the electrostatic protection circuit rises. An electrostatic stress to be applied to the internal circuit will increase.

On contrast therewith, a solid line (Q1+Q2) on the left of FIG. 2 (of the first example) shows a characteristic of the electrostatic protection circuit in which two types of the MOS transistors, which are the NMOS transistor Q1 having the thick gate insulating film and the NMOS transistor Q2 having the thin gate insulating film, are connected in parallel. A size ratio of the two types of the NMOS transistors is set to one to one, and a sum size is the same as each size of the transistors Q1 and Q2. As seen from FIG. 2, the operation start voltage that is substantially the same as an operation start voltage of the electrostatic protection circuit (of the comparative example 2) formed only of the NMOS transistor Q2 having the thin gate insulating film is obtained. That is, when an electrostatic stress is applied from outside, breakdown of the NMOS transistor Q2 having the thin gate insulating film occurs on the P-type semiconductor substrate, thereby raising a substrate potential. Then, the electrostatic protection circuit enters into a snapback mode, and a large current can be thereby flown. When the electrostatic stress further increases, the NMOS transistor Q1 having the thick gate insulating film starts operation. However, the substrate potential has already risen. Thus, the NMOS transistor Q1 having the thick gate insulating film starts operation at a voltage lower than the intrinsic operation start voltage of the NMOS transistor Q1. The operation start voltage of the NMOS transistor Q1 having the thick gate insulating film depends on a manner in which the substrate potential rises, which is related to the size of the NMOS transistor Q2 having the thin gate insulating film and an arrangement manner of the NMOS transistor Q2. When the substrate potential rises sufficiently, the NMOS transistor Q1 having the thick gate insulating film can start operation almost at the same time as the NMOS transistor Q2 having the thin gate insulating film. For this reason, the size and the arrangement manner of the NMOS transistor Q2 having the thin gate insulating film should be determined based on the relationship between the leak current and operation characteristics of the electrostatic protection circuit, and are not limited to this example.

According to the first example, the following effects are achieved. A first effect is that, by constituting the electrostatic protection circuit for the supply terminal N1 from the NMOS transistor Q1 with the thick gate insulating film and a high threshold voltage, the semiconductor device having a small standby current can be provided. A second effect is that, by connecting the NMOS transistor Q2 with the thin gate insulating film and a low threshold voltage to the electrostatic protection circuit for the supply terminal N1 in parallel, the semiconductor device can be provided in which the electrostatic protection circuit can be operated at a low voltage and a function of the electrostatic protection circuit will not be impaired when an electrostatic stress is applied.

### SECOND EXAMPLE

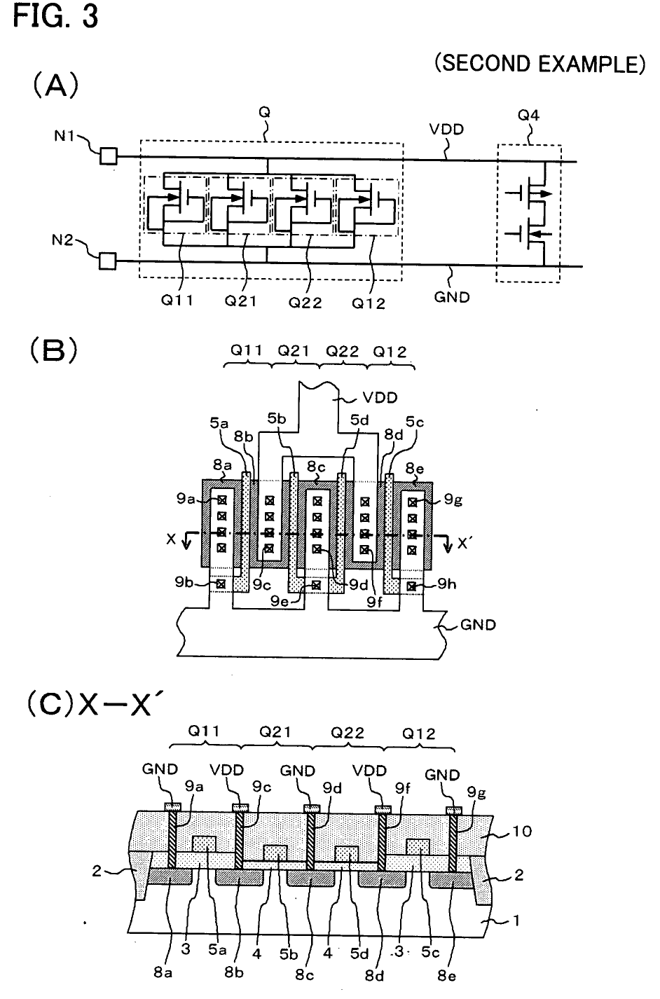

A semiconductor device according to a second example of the present invention will be described, using drawings. FIG. 3 includes diagrams schematically showing a configuration of the semiconductor device according to the second example of the present invention. (A) of FIG. 3 is a circuit diagram. (B) of FIG. 3 is a partial plan view of an electrostatic protection circuit. (C) of FIG. 3 is a partial sectional view taken along a line X-X′.

Referring to (A) of FIG. 3, the semiconductor device according to the second example includes an internal circuit Q4 with MOS transistors connected in series between the power supply (power supply line VDD) and the ground (ground line GND), and an electrostatic protection circuit Q with NMOS transistors Q11 and Q12 each having a thick gate insulating film and NMOS transistors Q21 and Q22 each having a thin gate insulating film all connected in parallel between the power supply and the ground. The electrostatic protection circuit Q is connected in parallel with the internal circuit Q4 between the power supply and the ground. One end of the power supply line VDD includes the power supply terminal N1. One end of the ground line GND includes the ground terminal N2. The size of each of the NMOS transistors Q1 and Q12 having the thick gate insulating film is the same as the size of each of the NMOS transistors Q21 and Q22 having the thin gate insulating film.

Referring to (B) and (C) of FIG. 3, the electrostatic protection circuit Q of the semiconductor device is constituted from the P-type semiconductor substrate 1, device separation regions 2, the first gate insulating film 3, the second gate insulating film 4, the first gate electrode 5a, a first gate electrode 5c, the second gate electrode 5b and a second gate electrode 5d, N-type impurity regions 8a to 8e, via holes 9a to 9h, an inter-layer insulating film 10, the power supply line VDD, and the ground line GND.

The P-type semiconductor substrate 1 is the P-type semiconductor substrate (silicon substrate), and is electrically connected to the ground (GND), though not shown. In place of the P-type semiconductor substrate 1, the P-type well may be employed. A device separation region 2 is the region that achieves electrical separation between devices by an insulator (such as silicon oxide film, or the like), and a structure of a LOCOS type or an STI type, for example, can be employed as the device separation region 2. The device separation region 2 achieves device separation from other device (not shown) in an outer periphery of a unit of the N-type impurity regions 8a to 8e.

The first gate insulating film 3 is the insulating film (such as the silicon oxide film, silicon oxo-nitride film, or the like) disposed at least between the first gate electrode 5a of the NMOS transistor Q11 and the channel of the NMOS transistor Q11 and the first gate electrode 5c of the NMOS transistor Q12 and the channel of the NMOS transistor Q12, and is formed to be thicker than the film thickness of the second gate insulating film 4. The second gate insulating film 4 is the insulating film (such as the silicon oxide film, silicon oxo-nitride film, or the like) disposed at least between the second gate electrode 5b of the NMOS transistor Q21 and the channel of the NMOS transistor Q21 and the second gate electrode 5d of the NMOS transistor Q22 and the channel of the NMOS transistor Q22, and is formed to be thinner than the film thickness of the first gate insulating film 3.

The first gate electrode 5a is the gate electrode made of a conductor (such as polysilicon, metal, or the like) disposed on the first gate insulating film 3 of the NMOS transistor Q11, and is electrically connected to the ground line GND through the via hole 9b. The second gate electrode 5b is the gate electrode made of the conductor (such as polysilicon, metal, or the like) disposed on the second gate insulating film 4 of the NMOS transistor Q21. The second gate electrode 5b is formed to be integral with the second gate electrode 5d and is electrically connected to the ground line GND through the via hole 9e. The first gate electrode 5c is a gate electrode made of the conductor (such as polysilicon, metal, or the like) disposed on the first gate insulating film 3 of the NMOS transistor Q12, and is electrically connected to the ground line GND through the via hole 9h. The second gate electrode 5d is a gate electrode made of the conductor (such as polysilicon, metal, or the like) disposed on the second gate insulating film 4 of the NMOS transistor Q22. The second gate electrode 5d is formed to be integral with the second gate electrode 5b, and is electrically connected to the ground line(GND) through the via hole 9e.

The N-type impurity regions 8a to 8e are the impurity regions in which impurities of the N type which is the conductivity type opposite to that of the P type substrate 1 are diffused. The N-type impurity regions 8a and 8b are disposed on both sides of the channel of the NMOS transistor Q11, and each of the N-type impurity regions 8a and 8b becomes a source/drain region of the NMOS transistor Q11. The N-type impurity regions 8b and 8c are disposed on both sides of the channel of the NMOS transistor Q21, and each of the N-type impurity regions 8b and 8c becomes a source/drain region of the NMOS transistor Q21. The N-type impurity regions 8c and 8d are disposed on both sides of the channel of the NMOS transistor Q22, and each of the N-type impurity regions 8c and 8d becomes a source/drain region of the NMOS transistor Q22. The N-type impurity regions 8d and 8e are disposed on both sides of the channel of the NMOS transistor Q12, and each of the N-type impurity regions 8d and 8e becomes a source/drain region of the NMOS transistor Q12. The N-type impurity region 8a is electrically connected to the ground line GND via the via hole 9a. The N-type impurity region 8b is common as the one source/drain region of each of the NMOS transistor Q11 and the NMOS transistor Q21, and is electrically connected to the power supply line VDD through the via hole 9c. The N-type impurity region 8c is common as the one source/drain region of each of the NMOS transistor Q21 and the NMOS transistor Q22, and is electrically connected to the ground line VDD through the via hole 9d. The N-type impurity region 8d is common as the one source/drain region of each of the NMOS transistor Q22 and the NMOS transistor Q12, and is electrically connected to the power supply line VDD through the via hole 9f. The N-type impurity region 8e is electrically connected to the ground line GND through the via hole 9g.

The via holes 9a to 9h are conductors embedded in base holes formed in the inter-layer insulating film 10 over the device separation regions 2, first gate insulating film 3, second gate insulating film 4, first gate electrodes 5a and 5c, and second gate electrodes 5b and 5d. The via hole 9a electrically connects the ground line GND and the N-type impurity region 8a. The via hole 9b electrically connects the ground line GND and the first gate electrode 5a. The via hole 9c electrically connects the power supply line VDD and the N-type impurity region 8b. The via hole 9d electrically connects the ground line GND and the N-type impurity region 8c. The via hole 9e electrically connects the ground line GND, second gate electrode 5b, and second gate electrode 5d. The via hole 9f electrically connects the power supply line VDD and the N-type impurity region 8d. The via hole 9g electrically connects the ground line GND and the N-type impurity region 8e. The via hole 9h electrically connects the ground line GND and the first gate electrode 5c.

The inter-layer insulating film 10 is an insulating film (such as the silicon oxide film, or the like) formed over the device separation regions 2, first gate insulating film 3, second gate insulating film 4, first gate electrodes 5a and 5c, and second gate electrodes 5b and 5d. The base holes for forming the via holes 9a to 9h are formed in predetermined locations of the inter-layer insulating film 10. The power supply line VDD is a line for power supply, made of a conductor (such as a metal) disposed on the inter-layer insulating film 10. The power supply line VDD is electrically connected to the N-type impurity region 8b through the via hole 9c. The power supply line VDD is electrically connected to the N-type impurity region 8d through the via hole 9f. The ground line GND is a line for grounding, made of the conductor (such as the metal) disposed on the inter-layer insulating film 10. The ground line GND is electrically connected to the N-type impurity region 8a through the via hole 9a. The ground line GND is electrically connected to the first gate electrode 5a through the via hole 9b. The ground line GND is electrically connected to the N-type impurity region 8c through the via hole 9d. The ground line GND is electrically connected to the second gate electrodes 5b and 5d through the via hole 9e. The ground line GND is electrically connected to the N-type impurity region 8e through the via hole 9g. The ground line GND is electrically connected to the first gate electrode 5c through the via hole 9h. The ground line GND extends like a teeth fashion of a comb, whereas the VDD line extends also like a teeth fashion. The VDD line teeth are disposed in every interval (gap) of the GND line teeth.

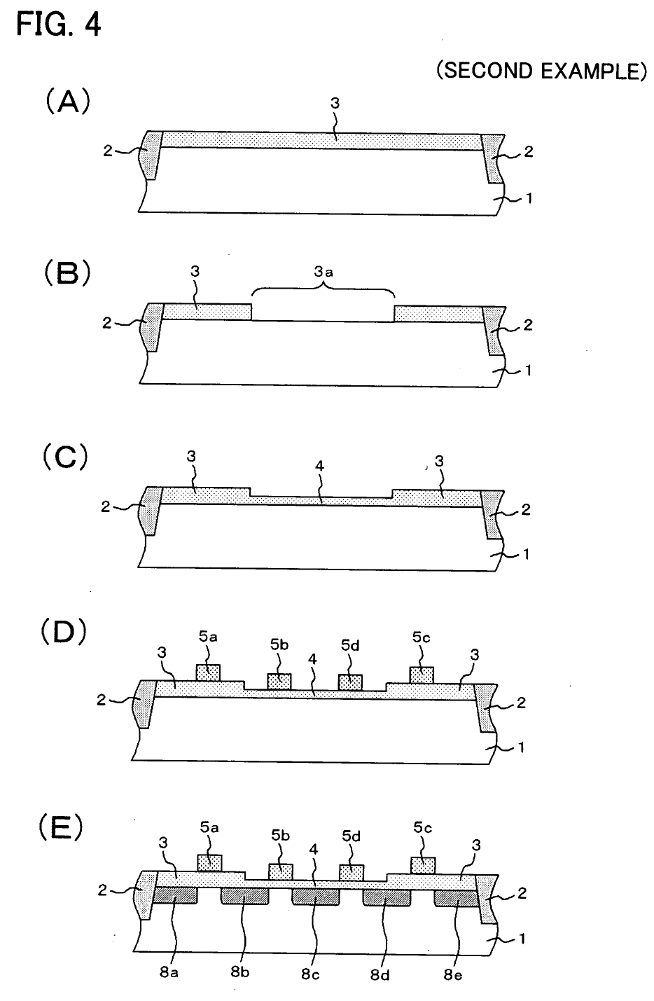

Next, a manufacturing method of the electrostatic protection circuit of the semiconductor device according to the second example of the present invention will be described, using drawings. FIG. 4 includes sectional views of steps in which the manufacturing method of the electrostatic protection circuit in the semiconductor device according to the second example of the present invention is schematically shown.

First, the device separation regions 2 are formed in the P-type semiconductor substrate 1. Then, the thick first gate insulating film 3 is formed by a method of thermal oxidation or the like (in step A1; refer to (A) of FIG. 4).

Next, an opening 3a obtained by selectively removing the first gate insulating film 3 in a region that will become the NMOS transistor having the thin gate insulating film (such as the transistor Q21 or Q22 in (C) of FIG. 3) is formed (in step A2; refer to (B) of FIG. 4). Incidentally, the opening 3a can be formed by first forming a photoresist on the first gate insulating film 3 and then performing etching with the photoresist used as a mask.

Next, the second gate insulating film 4 is formed on the region of the opening 3a (in step A3; refer to (C) of FIG. 4). Though the insulating film is also formed to a certain degree in a region of the thick first gate insulating film 3 as well at this point, a thickness of the thick first gate insulating film 3 formed first should be set in view of a film thickness that will be added when the thin second gate insulating film 4 is formed.

Next, the gate electrodes 5a to 5d are formed (in step A4; refer to (D) of FIG. 4). The gate electrodes 5a to 5d can be formed by forming polysilicon on the first gate insulating film 3 and the second gate insulating film 4, forming a photoresist on the polysilicon, then etching the photoresist as a mask, for example.

Next, the N-type impurity regions 8a to 8e are formed by, e.g., ion implanting (in step A5; refer to (E) of FIG. 4). Thereafter, by manufacturing the inter-layer insulating film 10, via holes 9a to 9h, power supply line VDD, and ground line GND according to usual MOS transistor manufacturing steps, the electrostatic protection circuit in (C) of FIG. 3 can be manufactured.

The second example has the same effect as the first example. Further, since a conventional method of manufacturing a plurality of MOS transistors having different gate insulating films, respectively, is adopted without alteration, an advantage that it is not necessary to add a new manufacturing step or change a manufacturing condition can be obtained.

### THIRD EXAMPLE

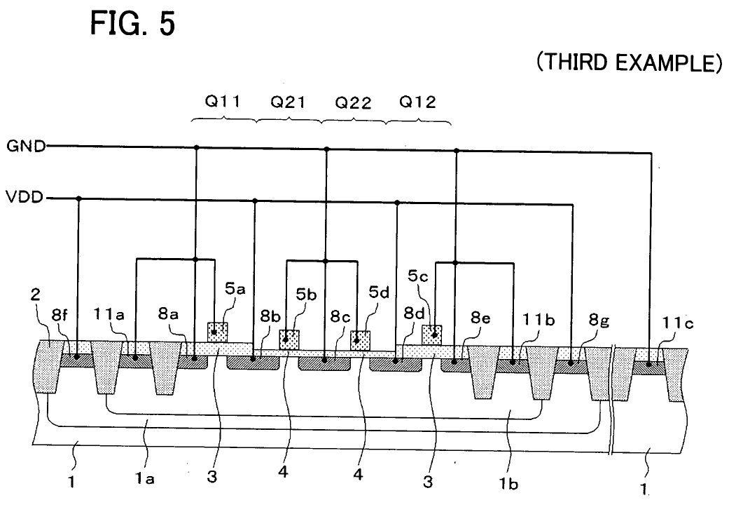

A semiconductor device according to a third example of the present invention will be described, using drawings. FIG. 5 is a partial sectional view schematically showing a configuration of the semiconductor device according to the third example of the present invention.

Around the electrostatic protection circuit (indicated by reference character Q in (A) of FIG. 3), common internal circuits (such as the internal circuit Q4 in (A) of FIG. 3) are arranged. At a time of an electrostatic discharge, an unwanted discharge may occur between one of the surrounding internal circuits through the P-type semiconductor substrate 1, thereby breaking down the internal circuit. For this reason, in the third example, an overall P well 1b associated with an electrostatic protection circuit is surrounded by an N well 1a of a conductive type opposite to that of the P-type semiconductor substrate 1, thereby electrically separating the P well 1b associated with the electrostatic protection circuit from the P-type semiconductor substrate 1. In the electrostatic protection circuit according to the third example, on a region of the P well 1b electrically separated from the P-type semiconductor substrate 1, the NMOS transistors Q1 and Q12 each having the thick gate insulating film and the NMOS transistors Q21 and Q22 each having the thin gate insulating film, which are the same as those in the second example, are formed.

The P well 1b is electrically connected to the ground (GND) through P-type impurity regions 11a and 11b having a high concentration, and therefore assumes the same potential as the ground (GND). The N well 1a is electrically connected to the power supply (VDD) through N-type impurity regions 8f and 8g having a high concentration, and therefore assumes the same potential as the power supply (VDD). The P-type semiconductor substrate 1 is electrically connected to the ground (GND) through a P-type impurity region 11c, and therefore assumes the same potential as the ground (GND).

According to the third example, the P well 1b associated with the electrostatic protection circuit is electrically separated from the P-type semiconductor substrate 1. Then, the NMOS transistors Q11 and Q12 each having the thick gate insulating film and the NMOS transistors Q21 and Q22 each having the thin gate insulating film are arranged in the same region of the P well 1b. An effect of increasing a substrate potential by the NMOS transistors Q21 and Q22 each having the thin gate insulating film thereby effectively acts on the NMOS transistors Q11 and Q12 each having the thick gate insulating film.

### FOURTH EXAMPLE

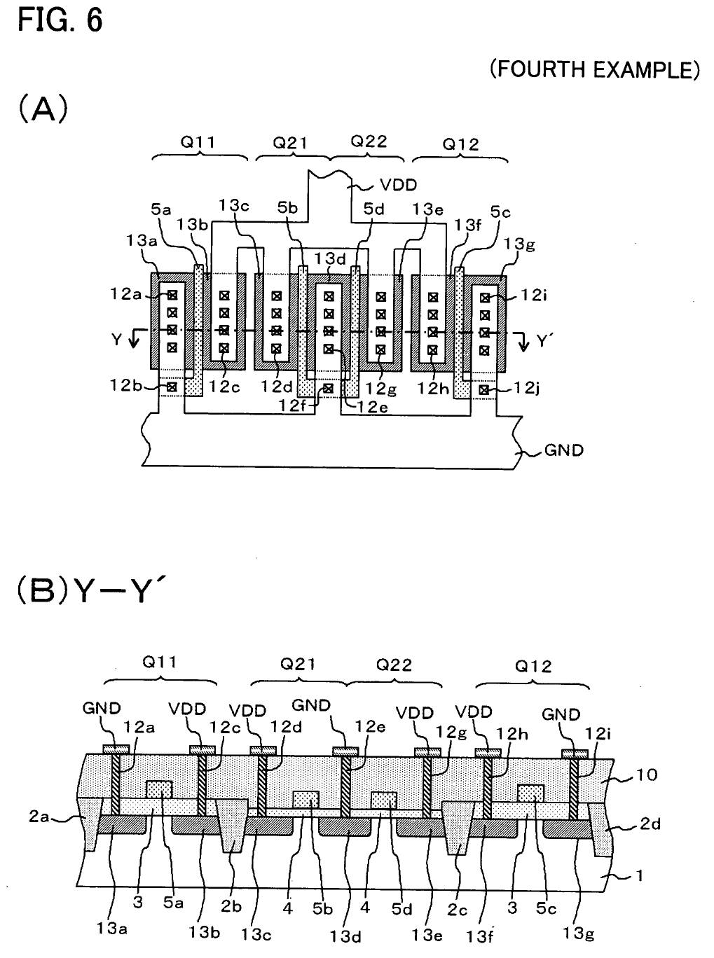

A semiconductor device according to a fourth example of the present invention will be described using drawings. FIG. 6 includes drawings schematically showing a configuration of the semiconductor device according to the fourth example of the present invention. (A) of FIG. 6 is a partial plan view of an electrostatic protection circuit, while (B) of FIG. 6 is a partial sectional view of the electrostatic protection circuit taken along a line Y-Y′.

Assume that the NMOS transistor Q11 having the thick gate insulating film and the NMOS transistor Q21 having the thin gate insulating film are formed to be adjacent to each other (or when the NMOS transistor Q12 having the thick gate insulating film and the NMOS transistor Q22 having the thin gate insulating film are formed to be adjacent to each other). Then, when the thick first gate insulating film 3 is partially removed as in the manufacturing step A2 in the second example (refer to (B) of FIG. 4), a shape abnormality such as an elevational (step) difference may occur at a boundary between the thick first gate insulating film 3 and the P-type semiconductor substrate 1 or the device separation region 2, depending on the manufacturing conditions. Then, this shape abnormality may cause discharge current concentration at a time of electrostatic application, thereby breaking down the electrostatic protection circuit.

Then, in order to prevent this phenomenon, separation of a region where the NMOS transistors Q11 and Q12 each having the thick gate insulating film from a region where the NMOS transistors Q21 and Q22 each having the thin gate insulating film is performed, in the fourth example.

A device separation region 2b is formed between the NMOS transistor Q11 having the thick gate insulating film and the NMOS transistor Q21 having the thin gate insulating film is formed, and a device separation region 2c is formed between the NMOS transistor Q12 having the thick gate insulating film and the NMOS transistor Q22 having the thin gate insulating film is formed. One source/drain region of each of the NMOS transistor Q11 and the NMOS transistor Q21 is not common, and the one source/drain region is separated into N-type impurity regions 13b and 13c by the device separation region 2b. One source/drain region of each of the NMOS transistor Q22 and the NMOS transistor Q12 is not common, and the one source/drain region is separated into N-type impurity regions 13e and 13f by the device separation region 2c.

In the NMOS transistor Q11, the first gate electrode 5a is formed above the channel via the thick first gate insulating film 3, and on both sides of the channel, an N-type impurity region 13a and the N-type impurity region 13b are formed. The first gate electrode 5a is electrically connected to the ground line GND through a via hole 12a. The N-type impurity region 13a is electrically connected to the ground line GND through a via hole 12b. The N-type impurity region 13b is electrically connected to the power supply line VDD through a via hole 12c. In the NMOS transistor Q12, the first gate electrode 5c is formed above the channel through the thick first gate insulating film 3, and on both sides of the channel, the N-type impurity region 13f and an N-type impurity region 13g are formed. The first gate electrode 5c is electrically connected to the ground line GND through a via hole 12j. The N-type impurity region 13f is electrically connected to the power supply line VDD through a via hole 12h. The N-type impurity region 13g is electrically connected to the ground line GND through a via hole 12i. In the NMOS transistor Q21, the second gate electrode 5b is formed above the channel through the thin second gate insulating film 4, and on both sides of the channel, the N-type impurity region 13c and an N-type impurity region 13d are formed. The second gate electrode 5b is formed to be integral with the second gate electrode 5d, and is electrically connected to the ground line GND through a via hole 12f. The N-type impurity region 13c is electrically connected to the power supply line VDD through a via hole 12d. The N-type impurity region 13d is common as one source/drain region of each of the NMOS transistor Q21 and the NMOS transistor Q22, and is electrically connected to the ground line GND through a via hole 12e. In the NMOS transistor Q22, the second gate electrode 5d is formed above the channel through the thin second gate insulating film 4, and on both sides of the channel, the N-type impurity regions 13d and 13e are formed. The second gate electrode 5d is formed to be integral with the second gate electrode 5b, and is electrically connected to the ground line GND through the via hole 12f. The N-type impurity region 13d is common as one source/drain region of each of the NMOS transistor Q21 and the NMOS transistor Q22, and is electrically connected to the ground line GND through the via hole 12e. An N-type impurity region 13e is electrically connected to the power supply line VDD through a via hole 12g. The P-type semiconductor substrate I is the semiconductor substrate (silicon substrate) of P type, and is electrically connected to the ground (GND), though not shown. Device separation regions 2a and 2d are regions each of which performs electrical separation between the devices by the insulator (such as the silicon oxide film or the like). The structure of the LOCOS type or the STI type can be employed as the device separation regions 2a and 2d. The device separation regions 2a and 2d achieve device separation from other device (not shown) in an outer periphery of a unit of the N-type impurity regions 13a to 13g. The device separation regions 2a and 2d are formed to be integral with the device separation regions 2b and 2c.

In the fourth example, separation between a region where the NMOS transistors Q11 and Q12 each having the thick gate insulating film are formed and a region where the NMOS transistors Q21 and Q22 each having the thin gate insulating film are formed is performed. Thus, the area of the electrostatic protection region slightly increases. Generally, a lot of NMOS transistors are connected in parallel in the electrostatic protection circuit, and among these transistors, only the two separation regions are present in the fourth example. Thus, an actual influence on the area is negligible.

### FIFTH EXAMPLE

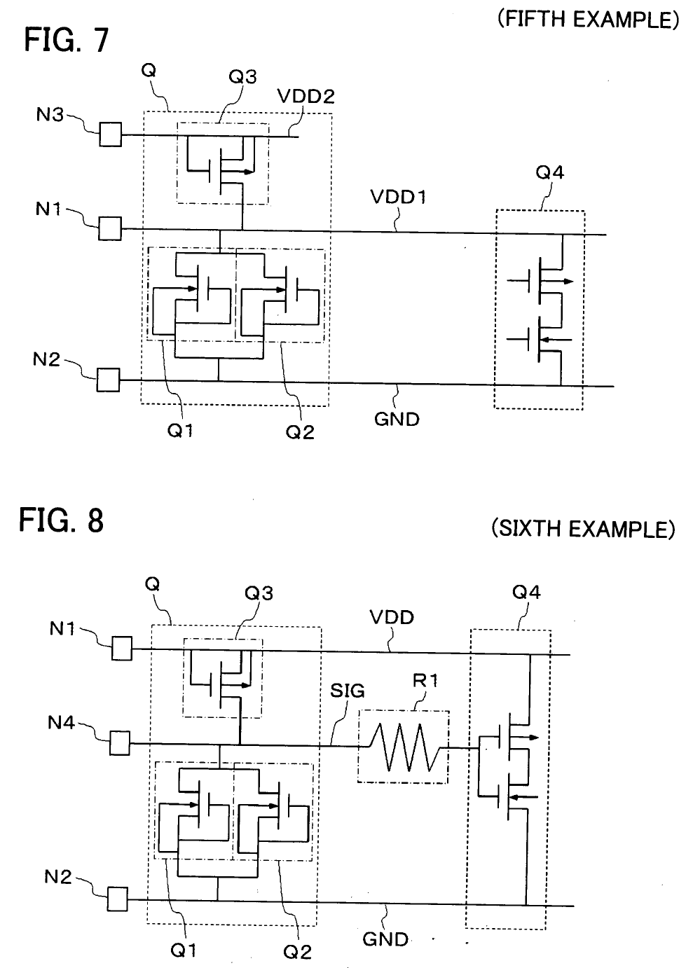

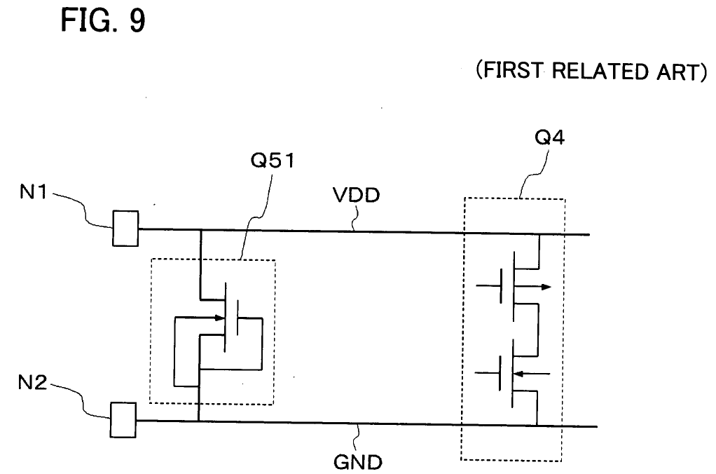

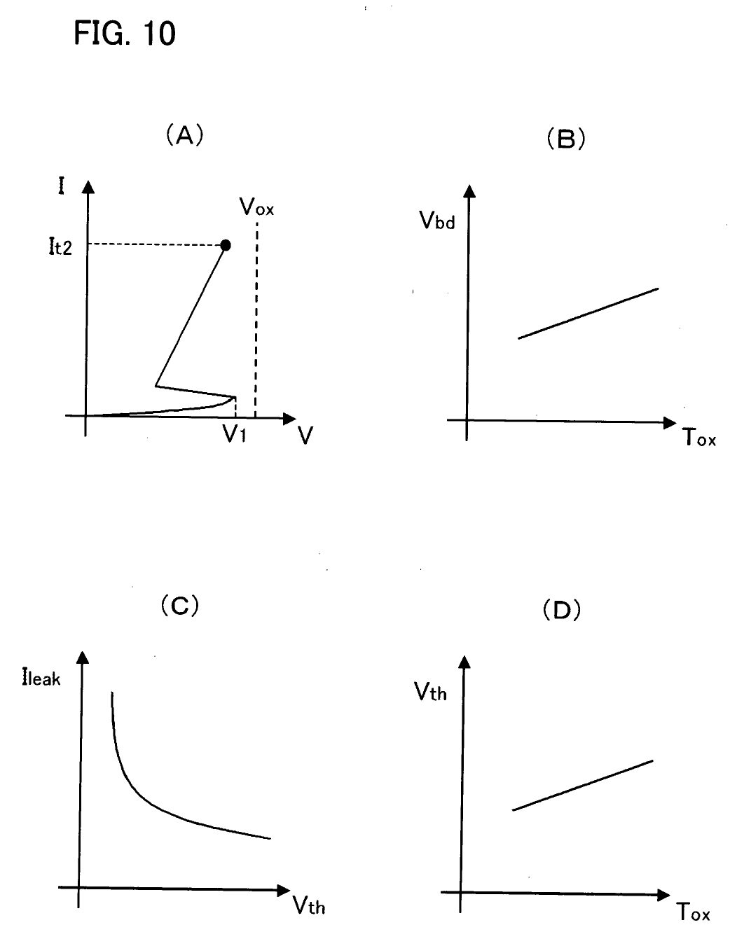

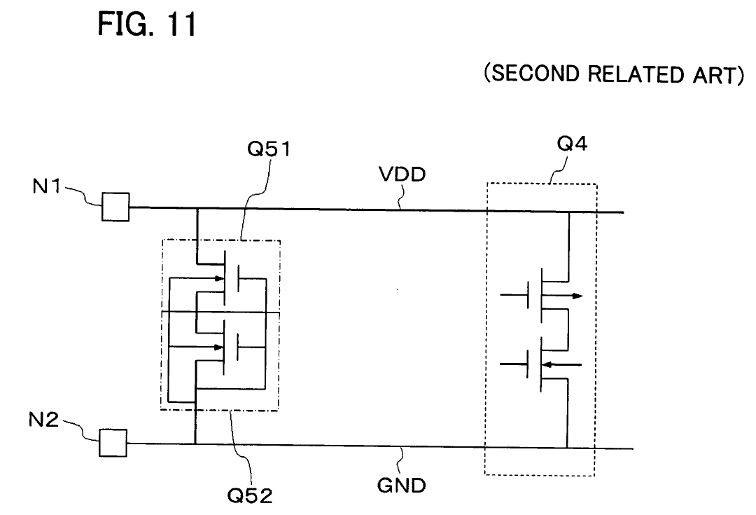

A semiconductor device according to a fifth example of the present invention will be described using drawings. FIG. 7 is a circuit diagram schematically showing a configuration of the semiconductor device according to the fifth example of the present invention.

In the semiconductor device according to the fifth example, the electrostatic protection circuit that is the same as the electrostatic protection circuit in the first example is combined with a further (other) electrostatic protection circuit. Referring to FIG. 7, the semiconductor device according to the fifth example is the semiconductor device in which the ground terminal N2 and the power supply terminal N1 and an additional power supply terminal N3 of two types are present. To the ground terminal N2, the ground line GND is electrically connected. To the first power supply terminal N1, the first power supply line VDD1 is electrically connected. To the second power supply terminal N3, a second power supply line VDD2 is electrically connected, and a potential higher than a potential at the first power supply terminal N1 is applied. The electrostatic protection circuit Q includes the electrostatic protection circuit in which the NMOS transistor Q1 having the thick gate insulating film and the NMOS transistor Q2 having the thin gate insulating film are connected in parallel between the first power supply line VDD1 and the ground line GND, and an electrostatic protection circuit in which a PMOS transistor Q3 is connected between the first power supply line VDD1 and the second power supply line VDD2.

A gate electrode of the PMOS transistor Q3 is electrically connected to the second power supply line VDD2, and one source/drain region of the PMOS transistor Q3 is electrically connected to the second power supply line VDD2. The other source/drain region of the PMOS transistor Q3 is electrically connected to the first power supply line VDD1. An N well of the PMOS transistor Q3 that constitutes a channel is electrically connected to the second power supply line VDD2. The electrostatic protection circuit in the first example can also be connected to the power supply terminal N3.

The fifth example can be applied to the semiconductor device in which the two types of the power supply terminals N1 and N3 are present, as well.

### SIXTH EXAMPLE

A semiconductor device according to a sixth example of the present invention will be described using drawings. FIG. 8 is a circuit diagram schematically showing a configuration of the semiconductor device according to the sixth example of the present invention.

In the first to fifth examples, the electrostatic protection circuit that includes the NMOS transistor Q1 having the thick gate insulating film and the NMOS transistor Q2 having the thin gate insulating film connected in parallel between the power supply terminal N1 and the ground terminal N2 is included. When a leak current needs to be reduced with respect to an input signal terminal N4, a configuration including an electrostatic protection circuit in which the NMOS transistor Q1 having the thick gate insulating film and the NMOS transistor Q2 having the thin gate insulating film are connected in parallel between the input signal terminal N4 and the ground terminal N2 may be employed. Incidentally, a data output terminal may be used in place of the input signal terminal N4.

In the sixth example, the electrostatic protection circuit having the same configuration as in the first example is connected between the input signal terminal N4 and the ground terminal N2, and one source/drain region of each of the NMOS transistor Q1 and the NMOS transistor Q2 is connected to a signal line SIG electrically connected to the input signal terminal N4. The gate electrode of each of the NMOS transistors Q1 and Q2, the other source/drain region of each of the NMOS transistors Q1 and Q2, and the P-type semiconductor substrate (or the P well) forming the channel of each of the NMOS transistors Q1 and Q2 are connected to the ground line GND electrically connected to the ground terminal N2. A PMOS transistor Q3 is connected between the power supply terminal N1 and the input signal terminal N4 via a signal line SIG. The gate electrode of the PMOS transistor Q3 is electrically connected to the power supply line VDD. The one source/drain region of the PMOS transistor Q3 is electrically connected to the power supply line VDD. The other source/drain region of the PMOS transistor Q3 is electrically connected to the signal line SIG, and the N well that forms the channel is electrically connected to the power supply line VDD. The signal line SIG is connected to gate electrodes of the internal circuit Q4 through a resistance element R1. The resistance element R1 is connected to protect the internal circuit Q4.

The sixth example can be applied also when it is necessary to reduce the leak current with respect to the input signal terminal N4.

In the fifth and sixth examples, the other electrostatic protection circuit Q3 to be combined with the NMOS transistors Q1 and Q2 is not always limited to the PMOS transistor. The electrostatic protection circuit of other structure such as a diode can also be employed, and a connecting destination can also be variously changed.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
an electrostatic protection circuit formed of a parallel connection of a first MOS transistor having a first threshold voltage and a second MOS transistor having a second threshold voltage lower than the first threshold voltage between two external terminals.

2. The semiconductor device according to claim 1, wherein said second MOS transistor has a film thickness of a gate insulating film thinner than that of said first MOS transistor.

3. The semiconductor device according to claim 1, wherein said first MOS transistor and said second MOS transistor are formed on a same substrate.

4. The semiconductor device according to claim 1, wherein a first external terminal of said two external terminals is one of a power supply terminal, an input signal terminal and a data output terminal; and
a second external terminal of said two external terminals is a ground terminal.

5. The semiconductor device according to claim 4, further comprising:
a third external terminal other than said two external terminals; and
a further electrostatic protection circuit connected between said first external terminal and said third external terminal.

6. The semiconductor device according to claim 5, wherein
said first MOS transistor and said second MOS transistor are NMOS transistors; and
said further electrostatic protection circuit is formed of a PMOS transistor.

7. The semiconductor device according to claim 4, wherein one of a source and a drain of said first MOS transistor is connected to said first external terminal;
one of a source and a drain of said second MOS transistor is connected to said first external terminal;
the other of said source and drain of said first MOS transistor and a gate electrode of said first MOS transistor are connected to said second external terminal;
the other of said source and drain of said second MOS transistor and a gate electrode of said second MOS transistor are connected to said second external terminal; and
a substrate or a well forming a channel of said first MOS transistor and a channel of said second MOS transistor is connected to said second external terminal.

8. The semiconductor device according to claim 7, wherein
said channel of said first MOS transistor and said channel of said second MOS transistor are formed in a first well;
a second well of a conductivity type opposite to a conductivity type of said first well and said substrate is disposed between said first well and said substrate; and
said second well is connected to said first external terminal.

9. The semiconductor device according to claim 1, wherein
said first MOS transistor and said second MOS transistor are adjacent to each other; and
one of said source and said drain of said first MOS transistor and one of said source and said drain of said second MOS transistor are common.

10. The semiconductor device according to claim 1, wherein said first MOS transistor and said second MOS transistor are adjacent to each other; and
the semiconductor device includes a device separation region that separates one of said source and said drain of said first MOS transistor from one of said source and said drain of said second MOS transistor.

11. A semiconductor device comprising:
a first electrostatic protection circuit connected across a signal line terminal and a ground terminal;
a second electrostatic protection circuit connected across said signal line terminal and the ground terminal; and
an internal circuit connected across said power supply terminal and the ground terminal;
said first electrostatic protection circuit being formed of a parallel connection of a first MOS transistor having a first threshold voltage and a second MOS transistor having a second threshold voltage lower than the first threshold voltage;
said signal line terminal being connected to a gate of said internal circuit via a resistance;
wherein said second electrostatic protection circuit is formed of a MOS transistor having a different conductive type from said first and second MOS transistors of the first electrostatic protection circuit.

12. The semiconductor device according to claim 11, wherein said second MOS transistor has a gate insulating film thinner than said first MOS transistor.

13. The semiconductor device according to claim 11, wherein said second electrostatic protection circuit is formed of a MOS transistor having a different conductive type from the MOS transistors of said first electrostatic protection circuit.

14. A semiconductor device comprising:
an electrostatic protection circuit connected across a power supply terminal and a ground terminal; and
an internal circuit connected across said power supply terminal and said ground terminal in parallel with said electrostatic protection circuit; wherein said electrostatic protection circuit is formed of a parallel connection of a first MOS transistor having a first threshold voltage and a second MOS transistor having a second threshold voltage lower than the first threshold voltage.

15. The semiconductor device according to claim 14, wherein said second MOS transistor has a gate insulating film thinner than said first MOS transistor.
